(19) United States
(12) Patent Application Publication
(10) Pub. No.: US 2012/0103264 A1
(43) Pub. Date: May 3, 2012

(54) METHODS AND APPARATUS FOR DEPOSITING A UNIFORM SILICON FILM WITH FLOW GRADIENT DESIGNS

(76) Inventors: SOO YOUNG CHOI, Fremont, CA (US); Tae Kyung Won, San Jose, CA (US); John M. White, Hayward, CA (US)

(21) Appl. No.: 13/349,332

(22) Filed: Jan. 12, 2012

Related U.S. Application Data
(62) Division of application No. 12/204,717, filed on Sep. 4, 2008.
Application No. 12/204,717 is a continuation of application No. 11/759,599, filed on Jun. 7, 2007, now abandoned.

(51) Int. Cl. C23C 16/455

(52) U.S. Cl. 118/728; 118/715

(57) ABSTRACT

Methods and apparatus having a flow gradient created from a gas distribution plate are provided. In one embodiment, the method and apparatus are particularly useful for, but not limited to, depositing a silicon film for solar cell applications. The apparatus for depositing a uniform film for solar cell applications includes a processing chamber, and a quadrilateral gas distribution plate disposed in the processing chamber and having at least four corners separated by four sides. The gas distribution plate further includes a first plurality of chokes formed through the gas distribution plate, the first plurality of chokes located in the corners, and a second plurality of chokes formed through the gas distribution plate, the second plurality of chokes located along the sides of the gas distribution plate between the corner regions, wherein the first plurality of chokes have a greater flow resistance than that of the second plurality of chokes.

### CROSS-REFERENCE TO OTHER APPLICATIONS

This application is a divisional application of co-pending U.S. patent application Ser. No. 12/204,717 (Attorney Docket No. APPM/011708.C1), filed on Sep. 4, 2008, which is a continuation of U.S. Ser. No. 11/759,599 (APPM/011708), filed Jun. 7, 2007, which is related to U.S. patent application Ser. No. 11/759,542, entitled “AN APPARATUS FOR DEPOSITING A UNIFORM SILICON FILM AND METHODS FOR MANUFACTURING THE SAME”, filed Jun. 7, 2007, (Attorney Docket No. APPM/11707), each of which is herein incorporated by reference.

### BACKGROUND OF THE DISCLOSURE

1. Field of the Invention

Embodiments of the invention generally relate to a gas distribution plate assembly and method for manufacturing the same in a processing chamber.

2. Description of the Background Art

Photovoltaic (PV) devices or solar cells are devices which convert sunlight into direct current (DC) electrical power. PV or solar cells typically have one or more p-i-n junctions. Each junction comprises two different regions within a semiconductor material where one side is denoted as the p-type region and the other as the n-type region. When the p-i-n junction of the PV cell is exposed to sunlight (consisting of energy from photons), the sunlight is directly converted to electricity through a PV effect. PV solar cells generate a specific amount of electric power and cells are tiled into modules sized to deliver the desired amount of system power. PV modules are created by connecting a number of PV solar cells and are then joined into panels with specific frames and connectors.

PV solar cells typically include a photoelectric conversion unit formed on a large transparent substrate. The photoelectric conversion unit includes a p-type, an intrinsic type (i-type), and a n-type silicon layer sequentially disposed on the transparent substrate. The silicon films that may be utilized to form the photoelectric conversion unit may include polysilicon (poly-silicon), microcrystalline silicon (pc-Si), and amorphous silicon (a-Si) films. Plasma enhanced chemical vapor deposition (PECVD) is generally employed to deposit the silicon films on the transparent substrate. PECVD process is performed by introducing a precursor gas or gas mixture into a vacuum chamber that includes the transparent substrate. The precursor gas or gas mixture is supplied from a distribution plate toward the surface of the transparent substrate. A RF power is applied to the distribution plate and/or a substrate support assembly disposed in the chamber to form a plasma from the precursor gas or gas mixture, subsequently depositing a silicon layer with desired film property on a surface of the transparent.

As the demand for larger solar cell substrates continues to grow, maintaining a uniform plasma and/or process gas flow during a PECVD process over the surface area of increasingly larger substrate has become increasingly difficult. Film property variation between the center and edge portions of deposited films present a significant challenge for producing large and efficient solar cells. With ever-increasing substrate size, edge to center property variation has become more problematic.

Therefore, there is a need for an improved apparatus for depositing a uniform film having desired properties on large area substrates by a chemical vapor deposition process.

### SUMMARY OF THE INVENTION

A method and apparatus for creating a flow gradient created from a gas distribution plate suitable for depositing a silicon film for solar cell applications are provided. In one embodiment, an apparatus for depositing films for solar cell applications may include a processing chamber, and a quadrilateral gas distribution plate disposed in the processing chamber and having at least four corners separated by four sides. The gas distribution plate further includes a first plurality of chokes formed through the gas distribution plate, the first plurality of chokes located in the corners, and a second plurality of chokes formed through the gas distribution plate, the second plurality of chokes located along the sides of the gas distribution plate between the corner regions, wherein the first plurality of chokes have a greater flow resistance than that of the second plurality of chokes.

In another embodiment, an apparatus for depositing films for solar cell applications may include a processing chamber, and a quadrilateral gas distribution plate disposed in the processing chamber and having at least 4 corners separated by four sides. The gas distribution plate further includes a first plurality of chokes formed through the gas distribution plate, the first plurality of chokes located in the corners, and a second plurality of chokes formed through the gas distribution plate, the second plurality of chokes located along the sides of the gas distribution plate between the corner regions, wherein the first plurality of chokes have a greater length than that of the second plurality of chokes.

In yet another embodiment, an apparatus for depositing a uniform film for solar cell applications may include a processing chamber, and a gas distribution plate disposed in the processing chamber having a plurality of chokes formed therethrough, the chokes arranged to define at least three different zones of flow resistance, wherein a first zone defined in the corners of the gas distribution plate has a flow resistance greater than a flow resistance of a second zone defined along the edge of the gas distribution plate, and a third zone defined in the center of the gas distribution plate has a flow resistance less than that of the second zone.

In still another embodiment, a method for depositing a uniform film for solar cell applications in a chamber may include providing a substrate into a chamber having a gas distribution plate facing a substrate support assembly disposed in the chamber, flowing process gas through corners of the gas distribution plate towards the substrate at a rate less than a rate of process gas flowing through the center of the gas distribution plate, and depositing a silicon film on the substrate from the process gas.

### BRIEF DESCRIPTION OF THE DRAWINGS

So that the manner in which the above recited features of the present invention are attained and can be understood in detail, a more particular description of the invention, briefly summarized above, may be had by reference to the embodiments thereof which are illustrated in the appended drawings.

FIG. 1 depicts a schematic cross-sectional view of one embodiment of a process chamber;

FIGS. 2A-C depict cross sectional view of a gas distribution plate at different stages of fabrication that produces a flow gradient;

FIGS. 3A-B depict cross sectional view of a gas distribution plate that produces a flow gradient at different stages of fabrication;

FIGS. 4A-B depict cross sectional view of another embodiment of a gas distribution plate that produces a flow gradient at different stages of fabrication;

FIG. 5 depicts one embodiment of a thermal treatment process suitable for manufacturing a gas distribution plate;

FIGS. 6A-B depict different stages of the thermal treatment process described in FIG. 5;

FIG. 7 depicts one embodiment of chokes that may be formed in a gas distribution plate;

FIG. 8 depicts a cross sectional view of another embodiment of a gas distribution plate having different configuration of chokes formed therethrough;

FIGS. 9A-C depict another embodiment of a gas distribution plate having a plurality of chokes that provide a flow gradient of gases;

FIGS. 10A-D depict different embodiments of chokes that may be formed in a gas distribution plate;

FIGS. 11A-B depict cross sectional views of a gas distribution plate at different stages of a process flow for manufacturing the gas distribution plate;

FIGS. 12A-B depict cross sectional views of another embodiment of a gas distribution plate having different choke configurations formed in a center and an edge portion of the plate;

FIG. 13 depicts a schematic plot of a bottom view of a gas distribution plate;

FIGS. 14A-B depict an exemplary embodiment of a cross sectional view of a plate having different choke configurations formed in different zones of the plate;

FIG. 15 depicts another embodiment of a top view of a gas distribution plate;

FIGS. 16A-B depict a cross sectional view of the gas distribution plate 1500 of FIG. 15 taken along with the line A-A;

FIGS. 17A-17C depict different embodiments of an adaptor plate 1700 that may have different choke configurations formed therein;

FIGS. 18A-C depict a cross sectional view of the gas distribution plate 1500 of FIG. 15 taken along with the line B-B; and

FIGS. 19A-19B depict plain views of different embodiments of curved gas distribution plates.

To facilitate understanding, identical reference numerals have been used, where possible, to designate identical elements that are common to the figures. It is contemplated that elements and features of one embodiment may be beneficially incorporated in other embodiments without further recitation.

It is to be noted, however, that the appended drawings illustrate only exemplary embodiments of this invention and are therefore not to be considered limiting of its scope, for the invention may admit to other equally effective embodiments.

### DETAILED DESCRIPTION

Methods and apparatus for depositing a silicon film suitable for solar cell applications are provided. In one embodiment, the apparatus includes a gas distribution plate having different choke lengths to create a gradient of gases flowing toward a substrate. The flow gradient created by the gas distribution plate provides a flexible control of edge to corner distribution of process gases provided through the gas distribution plate to the substrate surface. The controlled distribution of gases across a substrate enhances the ability to adjust thickness and/or profile of films deposited on the substrate. The flow gradient created by different choke lengths in the gas distribution plate also provides a process control attribute which facilitates controlling film property variation over the width of the substrate.

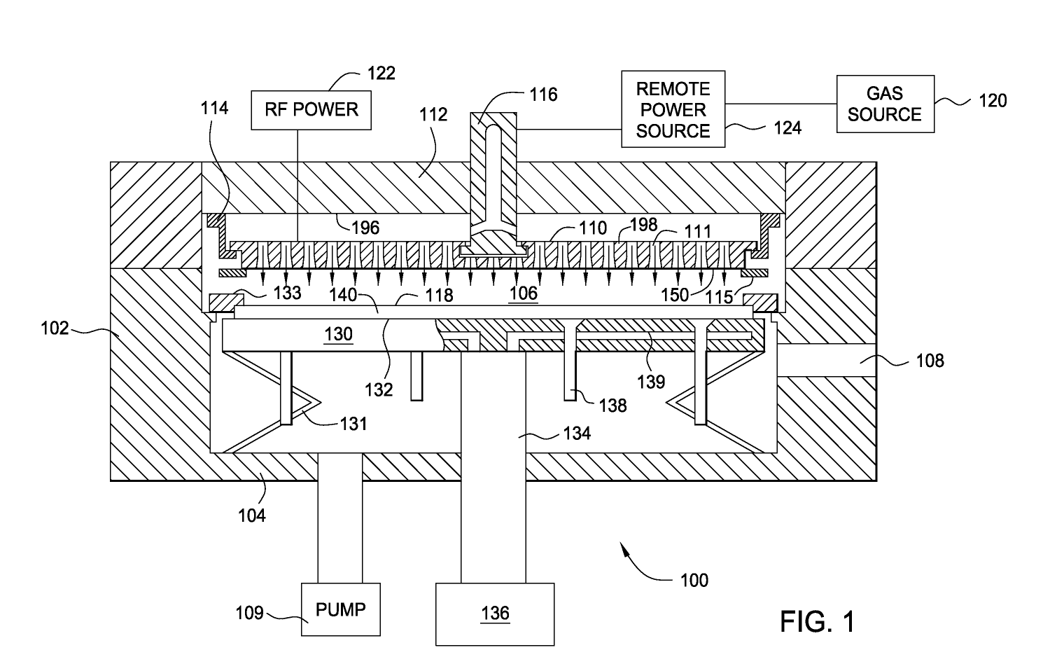

FIG. 1 is a schematic cross-section view of one embodiment of a plasma enhanced chemical vapor deposition (PECVD) chamber 100 in which one or more films suitable for fabricating a solar cell or other large area devices may be formed. One suitable plasma enhanced chemical vapor deposition chamber is available from Applied Materials, Inc., located in Santa Clara, Calif. It is contemplated that other deposition chambers, including those from other manufacturers, may be utilized to practice the present invention. It is also contemplated that the techniques described herein may be beneficially utilized to fabricate other structures or devices.

The chamber 100 generally includes walls 102 and a bottom 104 which bound a process volume 106. A gas distribution plate 110 and substrate support assembly 130 are disposed in the process volume 106. The process volume 106 is accessed through a slit valve passage 108 formed through the wall 102 which enables a substrate 140 to be transferred in and out of the chamber 100.

The substrate support assembly 130 includes a substrate receiving surface 132 for supporting the substrate 140 thereon. A stem 134 couples the support assembly 130 to a lift system 136 which raises and lowers the substrate support assembly 130 between substrate transfer and processing positions. A shadow frame 133 may be optionally placed over periphery of the substrate 140 when processing to prevent deposition on the edge of the substrate 140. Lift pins 138 are moveably disposed through the substrate support assembly 130 and are adapted to space the substrate 140 from the substrate receiving surface 132 to facilitate exchange of the substrate with a robot blade. The substrate support assembly 130 may also include heating and/or cooling elements 139 utilized to maintain the substrate support assembly 130 at a desired temperature. The substrate support assembly 130 may also include grounding straps 131 to provide RF grounding around the periphery of the substrate support assembly 130. Examples of grounding straps are disclosed in U.S. Pat. No. 6,024,044 issued on Feb. 15, 2000 to Law, et al. and U.S. Patent application Ser. No. 11/613,934 filed on Dec. 20, 2006 to Park, et al., which are incorporated by reference in their entireties.

The gas distribution plate 110 is coupled to a backing plate 112 at its periphery by a suspension 114. The gas distribution plate 110 may also be coupled to the backing plate 112 by one or more center supports 116 to help prevent sag and/or control the straightness/curvature of the gas distribution plate 110. In one embodiment, the gas distribution plate 110 may be in different configurations with different dimensions. In an exemplary embodiment, the gas distribution plate 110 is a quadrilateral gas distribution plate. The gas distribution plate 110 has an upper surface 198 and a downstream surface 150. The upper surface 198 faces a lower surface 196 of the backing plate 112. The gas distribution plate 110 includes a plurality of chokes 111 formed therethrough and facing an upper surface 118 of a substrate disposed on the substrate support assembly 130. The chokes 111 may have different shape, numbers, densities, dimensions, and distributions across the gas distribution plate 110. The diameter of the chokes 111 may be selected between about 0.01 inch and about 1 inch. A gas source 120 is coupled to the backing plate 112 to provide gas to a plenum defined between the gas distribution plate 110 and backing plate 112. The gas from the source 120 flows from the chokes 111 formed in the gas distribution plate 110 to the process volume 106.

In one embodiment, the chokes 111 in different regions of the plate 110 have different fluid conductance, thereby creating a flow gradient entering the process volume 106. The length, shape, profile, bore roughness and/or other attribute of the chokes 111 may be utilized to control the conductance of each choke 111. As different conductance of the chokes 111 may allow different amounts of process gases into the process volume 106, the flow gradient created across the substrate surface 118 may be efficiently utilized and configured to adjust the profile, film properties and thickness deposited on the substrate surface 118. It has been discovered that by having a different conductance of the corners of the distribution plate 110 relative to the edges of the plate 110, film property uniformity can be improved.

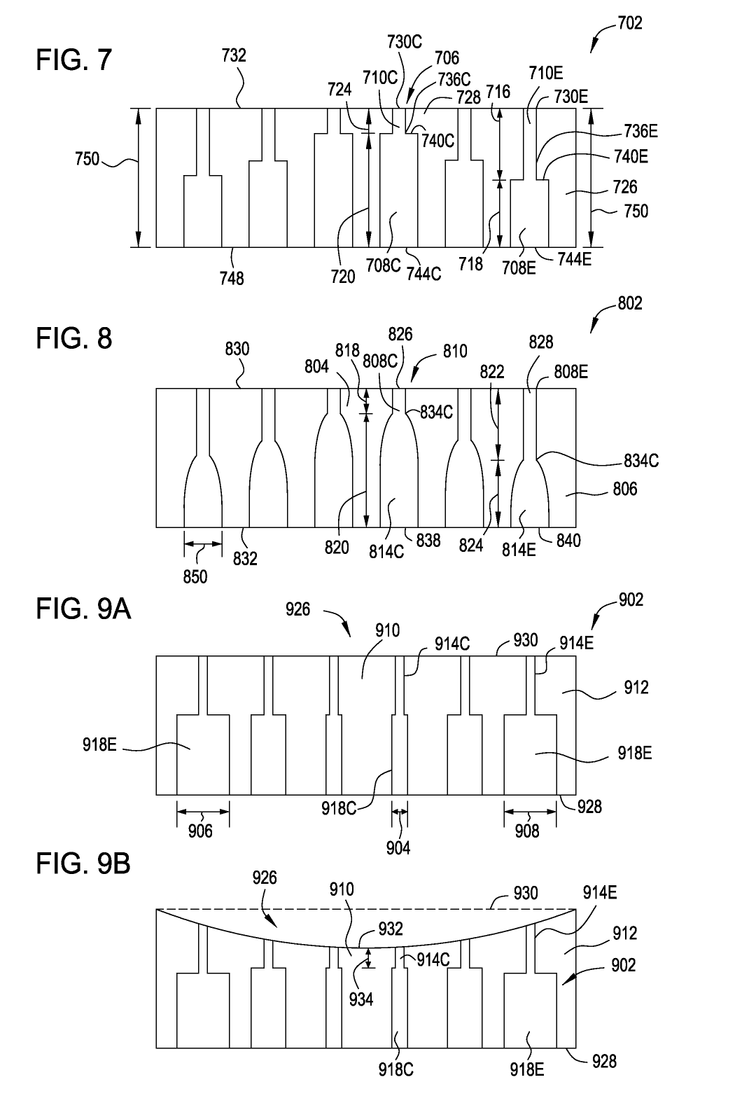

In one embodiment, different length of the chokes 111 may be formed by machining a portion of the plate 110 from the upper surface 198 and/or from the downstream surface 150 of the plate 110, thereby resulting in the chokes 111 located in the machined portion having a shorter length than the chokes 111 located in the un-machined portion. Alternatively, the lengths of the chokes 111 may be formed by including one or more bores formed concentrically to the chokes 111 to create different passage configurations in the gas distribution plate 110, which will be further described in detail below with reference to FIGS. 7-10D.

A vacuum pump 109 is coupled to the chamber 100 to maintain the process volume 106 at a desired pressure. A RF power source 122 is coupled to the backing plate 112 and/or to the gas distribution plate 110 to provide a RF power to create an electric field between the gas distribution plate 110 and the substrate support assembly 130 so that a plasma may be generated from the gases present between the gas distribution plate 110 and the substrate support assembly 130. Various RF frequencies may be used, such as a frequency between about 0.3 MHz and about 200 MHz. In one embodiment the RF power source is provided at a frequency of 13.56 MHz. Examples of gas distribution plates are disclosed in U.S. Pat. No. 6,477,980 issued on Nov. 12, 2002 to White et al., U.S. Publication No. 20050251990 published on Nov. 17, 2005 to Choi, et al., and U.S. Publication No. 2006/0060138 published on Mar. 23, 2006 to Keller, et al, which are all incorporated by reference in their entireties.

A remote plasma source 124, such as an inductively coupled remote plasma source, may also be coupled between the gas source and the backing plate. Between processing substrates, a cleaning gas may be energized in the remote plasma source 124 to provide a remotely generated plasma utilized to clean chamber components. The cleaning gas may be further excited by the RF power provided to the gas distribution plate 110 by the power source 122. Suitable cleaning gases include, but are not limited to, NF₃, F₂, and SF₆. Examples of remote plasma sources are disclosed in U.S. Pat. No. 5,788,778 issued Aug. 4, 1998 to Shang, et al, which is incorporated by reference.

In one embodiment, the substrate 140 that may be processed in the chamber 100 may have a surface area of 10,000 cm² or more, such as 40,000 cm² or more, for example about 55,000 cm² or more. It is understood that after processing the substrate may be cut to form smaller solar cells or other devices.

In one embodiment, the heating and/or cooling elements 139 may be set to maintain a substrate support assembly temperature during deposition of about 400 degrees Celsius or less, for example between about 100 degrees Celsius and about 400 degrees Celsius, or between about 150 degrees Celsius and about 300 degrees Celsius, such as about 200 degrees Celsius.

The spacing during deposition between the top surface of a substrate disposed on the substrate receiving surface 132 and the gas distribution plate 110 may be between 400 mil and about 1,200 mil, such as between 400 mil and about 800 mil.

For deposition of silicon films, a silicon-based gas and a hydrogen-based gas are provided through the gas distribution plate 110. Suitable silicon based gases include, but are not limited to silane (SiH₄), disilane (Si₂H₆), silicon tetrafluoride (SiF₄), silicon tetrachloride (SiCl₄), dichlorosilane (SiH₂Cl₂), and combinations thereof. Suitable hydrogen-based gases include, but are not limited to hydrogen gas (H₂). The p-type dopants of the p-type silicon layers may comprise a group III element, such as boron or aluminum. In one embodiment, boron is used as the p-type dopant. Examples of boron-containing sources include trimethylboron (TMB), diborane (B₂H₆), BF₃, B(C₂H₅)₃, BH₃, BF₃, and B(CH₃)₃ and similar compounds. In another embodiment, TMB is used as the p-type dopant. The n-type dopants of the n-type silicon layer may comprise a group V element, such as phosphorus, arsenic, or antimony. Examples of phosphorus-containing sources include phosphine and similar compounds. The dopants are typically provided with a carrier gas, such as hydrogen, argon, helium, or other suitable compounds. In the process regimes disclosed herein, a total gas flow rate of hydrogen based gas is provided. Therefore, if a hydrogen based gas is provided as the carrier gas, such as for the dopant, the carrier gas flow rate should be subtracted from the total gas flow rate of the hydrogen based gas to determine how much additional hydrogen based gas should be provided to the chamber.

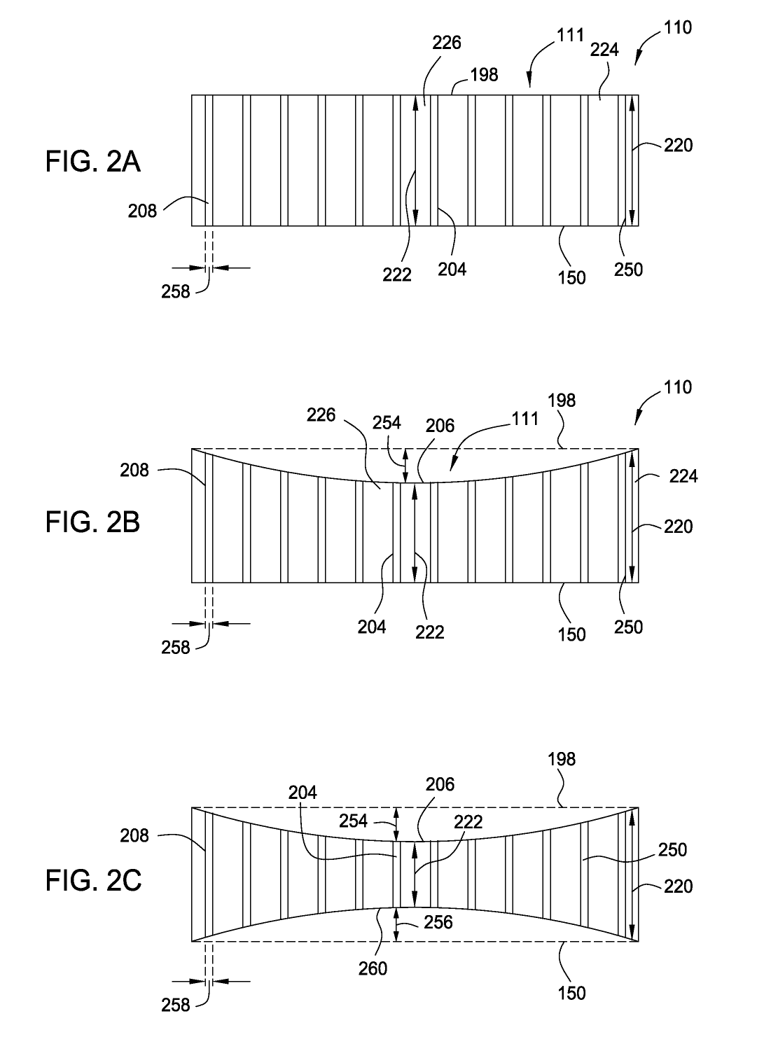

FIGS. 2A-C depict cross sectional views of a gas distribution plate at different stages of a fabrication sequence. The gas distribution plate 110 has the upper surface 198 facing the backing plate 112 and the opposing downstream surface 150 facing the substrate support assembly 130. In one embodiment, the upper surface 198 and the downstream surface 150 may be parallel planar surfaces. As discussed above, the chokes 111 may have different configurations, shape, features, and numbers to meet different process requirement. In the embodiment depicted in FIG. 2A, the chokes 111 in both a corner portion 224 and the edge portion 226 of the plate 110 may have straight walls with equal lengths 220, 222. The upper surface 198 and/or downstream surface 150 of the plate 110 may be machined or otherwise formed into a concave surface 206 relative to the lower surface 196 of the backing plate 112 and/or upper surface 132 of the substrate support assembly 130. In embodiments where the machining process removes a portion of the upper surface 198 of the plate 110, a concave surface 206 is created in the plate 110 resulting in the center portion 226 of the plate 110 being thinner than the corner portion 224, as shown in FIG. 2B. In one embodiment, a chord depth 254 created between the curved surface 206 and the original flat surface (as shown in phantom 198) may be configured to be between about 0.05 inch and about 1 inch. The chord depth 254 formed between the curved surface 206 and the original flat surface (as shown in phantom 198) is small relative to the size of the plate 110. In one embodiment, the maximum chord depth 254 may be controlled at a length no more than about 3 percent of the characteristic length of the plate 110, such as between about 0.1 percent and about 2.0 percent. For purpose of comparing the chord depth 254 to a rectangular or circular plate, the characteristic length is considered to be the “equivalent radius”. For a circular diffuser, the equivalent radius is equal to the radius of the plate. For a square or rectangular plate, the equivalent radius is one half of the diagonal. In the embodiment of the plate 110 having a dimension of about 2200 mm×1870 mm, the equivalent radius is about 1440 mm and the maximum chord depth 304 is about 28.4 mm.

The chokes 204 formed in the edge portion 226 of the plate may have a shorter length 222 (and thus, less resistance) than the length 220 of the chokes 250 formed at the corner portion 224. Additionally, the curved surface 206 of the plate 110 may be optionally configured so that the length of the chokes 111 at the edge of the plate 110 is greater than the lengths of the chokes located near the center of the plate 110. The gradually changing length of the chokes 111 creates different flow resistance through the plate 110, thereby causing a varied flow rate and/or volume rate profile of processing gases flowing through the gas distribution plate 110 and into the process volume 106. Particularly, the chokes are configured to reduce the conductance through the plate 110 at the corners relative to the edges of the plate 110. The different amounts of processing gases flowing through the gas distribution plate 110 create a flow gradient in the processing volume 106. The gradient may be selected to prove a process control knob for adjusting the deposited film profile, properties, uniformity of the film properties, and thickness, and/or the physical attributes of the deposited film. Thus, the use of the gas distribution plate 110 may be utilized to improve the cover to edge and edge to center crystal fraction ration in deposited silicon films.

The flow gradient assists may also be used to tune the center to edge uniformity of deposited films. For example, in an embodiment wherein a film would be deposited in a generally dome-shape film profile using a conventional gas distribution plate (e.g., a film profile having a center portion thicker than an edge portion), a shorter length of chokes located in a center portion of the plate 110 relative to chokes disposed near the edge portion 226 and corner portion 226 may be utilized to tune the film profile deposited formed on the substrate 140 to a more planar configuration. In contrast, in an embodiment wherein a film would be deposited in a generally concave-type film profile using a conventional gas distribution plate (e.g., a film profile having a center portion thinner than an edge portion), a longer length of chokes 250 located in the center portion relative to chokes disposed near the edge portion may be utilized.

In another embodiment, the downstream surface 150 of the plate 110 may be machined or otherwise formed to have a concave surface 260 relative to the upper surface 132 of the substrate support assembly 130. The machining process removes a portion of the plate 110 from the downstream surface 150 of the plate 110 so that the center of the edge portion 226 of the plate 110 is thinner than the corner portion 224, as shown in FIG. 2C. The curved surface 260 of the plate 110 creates a gradually changing distance between the curved surface 260 to the substrate support assembly 130 upon installation of the plate 110 in the chamber 100. In one embodiment, a chord depth 256 created between the curved surface 260 and the original flat surface (as shown in phantom 150) is between about 0.05 inch and about 1 inch. As the distance between the downstream curved surface 260 and the substrate support assembly 130 is gradually changed across the substrate support surface 132, the deposition profile of the film may be controlled. The curved upper surface 206 of the plate 110 in combination with the curved downstream surface 260 create both flow gradient and gradient spacing across the substrate surface 118 during processing, thereby providing enhanced control of gas and/or plasma distribution across the substrate surface allowing efficient control of the profile, properties, uniformity of the film properties, and thickness of the deposited film.

In one embodiment, the chokes 111 have a diameter 258 selected in a range that produces hollow cathode effect. During deposition, a plasma is generated to ionize the gas mixture supplied in the chamber. With a selected range of choke diameters, the plasma may reside in the chokes 111 of the gas distribution plate 110, thereby increasing electron emission, oscillation movement of electrons, and gas ionization, which is known as “hollow cathode effect”. Other embodiments where the geometry of the chokes 111 is selected, for example with small diameters less than or more than a diameter that provides the hollow cathode effect, the plasma will not reside in the chokes 111, thereby eliminating undesired over reaction and/or over depositing. In one embodiment, the diameter 238 of the chokes 111 has a diameter between about 0.05 inch and about 0.5 inch to create a desired amount of hollow cathode effect.

In some embodiments wherein a hollow cathode effect is not desired, the diameter 238 of the chokes 111 may be selected between about 0.01 inch and about 0.05 inch. Additionally, the chokes 111 formed on the downstream surface 150, as shown in FIG. 2B, and/or curved downstream surface 260, formed in FIG. 2C, may have different opening configuration to control the occurrence of hollow cathode gradient in the chokes 111. Different configurations for creating hollow cathode effect and/or gradient will be further described with reference to FIGS. 7-9.

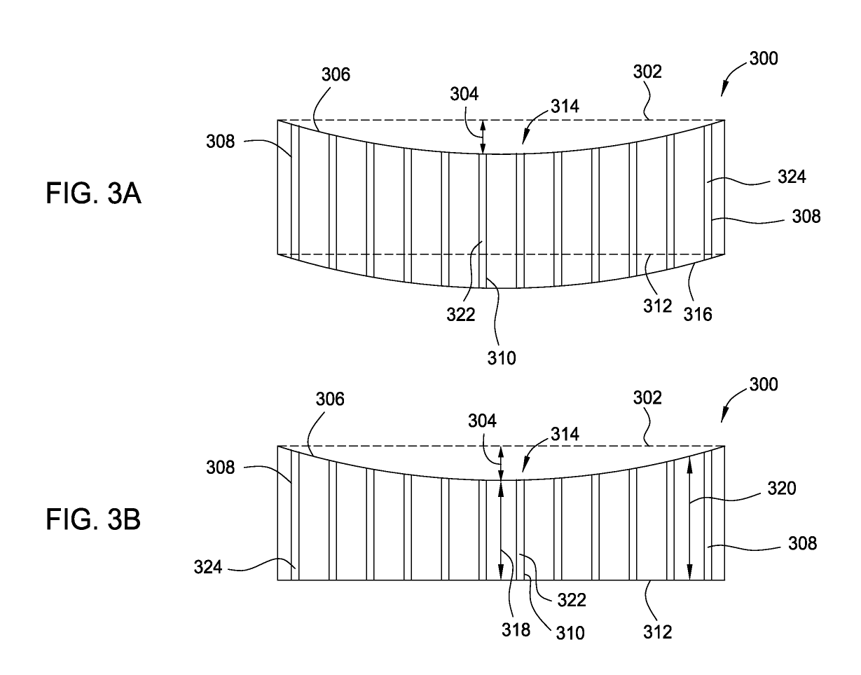

FIGS. 3A-B depict cross sectional views of a gas distribution plate 300 at different stages of a manufacturing process for the gas distribution plate 300 that creates an edge to corner flow gradient. Similar to the designs of the gas distribution plate 110 depicted in FIGS. 1 and 2A-C, a plurality of chokes 314 may be formed through the plate 300, as shown in FIG. 3A. The plate 300 then is deformed and/or machined to make a concave upper surface 306 from a flat surface (as shown in phantom surface 302) of the plate 300. This process may also cause a downstream surface 316 of the plate 300 to become a convex surface 316. Subsequently, the convex surface 316 in the edge portion 310 is machined to form a flat surface 312, leaving the upper surface 306 in the desired concave shape, which results the chokes 314 in the center of the edge portion 310 and the corner portion 308 of the plate 300 having different lengths 318, 320, as shown in FIG. 3B. It is noted that the deformation of the chokes 314 caused by the manufacturing process is not depicted in the Figures for sake of clarity.

Similar to the chokes 111 formed in FIGS. 1 and 2A-C, the chokes 314 may have straight walls with equal lengths 320, 318 at the corner and edge portions 308, 310 of the plate 300 at the beginning of the fabrication process. For ease of explanation, certain chokes 314 will now be referenced to as inner chokes 322 and outer chokes 324. The inner chokes 322 are located near the center of the edge portion 310 of the plate 300 and the corner chokes 324 are located near the corner portion 308 of the plate 300. As the plate 300 is deformed to make the upper surface 302 into the curved surface 306, the size, length, depth, and configuration of the chokes 314 formed in the plate 300 are changed by the deforming process as well. For example, as the downstream surface 312 of the plate 300 is curved to form a convex surface, a portion of the chokes 322 located in the edge portion 310 of the plate 300 are correspondingly machined, thereby resulting in the length of the chokes 322 in the edge portion 310 of the plate 300 becoming shorter than the length of the chokes 324 in the corner portion 308. Additionally, the deformation of the chokes 322 in the concave upper surface 306 created by the bending and/or deforming process may also result in the chokes 322 have inner walls with different length and/or inner curvature, thereby assisting creating flow gradient when gases passed through the plate 300. By a well defined and calculated machining and/or bending process, the depths, lengths, distributions, shapes, and densities of the chokes may be predetermined to create a desired gas and/or plasma distribution across the surface of the substrate positioned on the substrate support assembly 130, thereby facilitating control of thickness profile and properties of films deposited on the substrate.

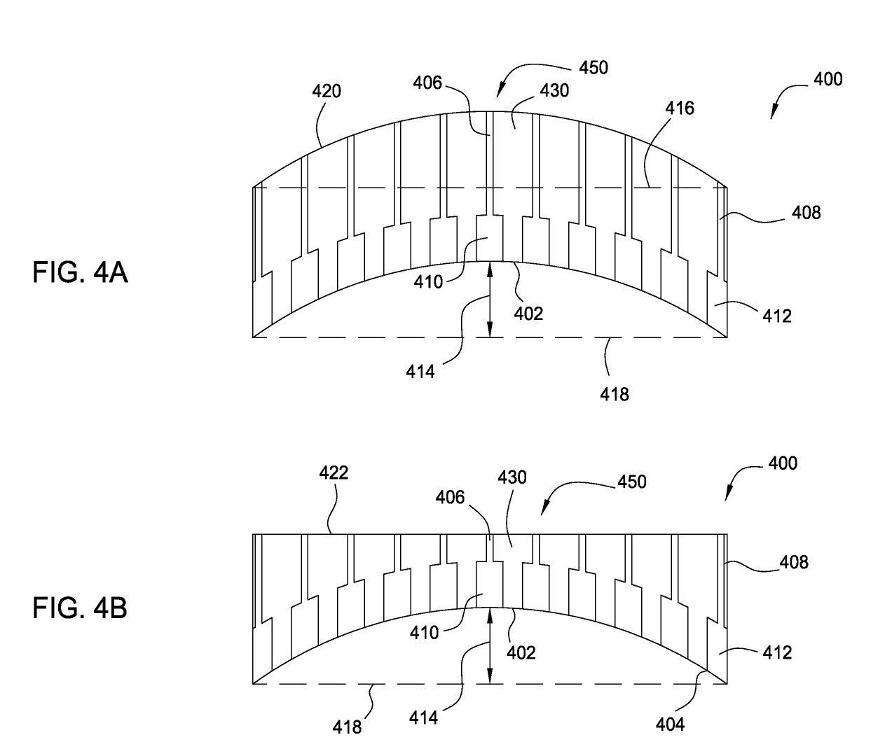

FIG. 4A-B depicts cross sectional views of a gas distribution plate 400 at different stages of a process flow for manufacturing the gas distribution plate 400 with a curved surface. A plurality of chokes 450 may be formed through the plate 400, as shown in FIG. 4A. The plate 400 is deformed to make a concave downstream surface from a flat surface (as shown in phantom surface 418) of the plate 400. This process may also cause an upper surface 420 of the plate 400 to become convex from flat to a convex surface 420. Subsequently, the convex surface 420 in the center of the edge portion 430 is machined to form a flat surface 422, leaving the downstream surface 402 in the desired concave shape, as shown in FIG. 4B. It is noted that the deformation of the chokes 450 caused by the deformation manufacture process is not depicted in the Figures for sake of clarity. A chord depth 414 defined between the curved surface 402 and the original flat surface (as shown in phantom 418) is between about 0.05 inch and about 1 inch, thereby creating a gradually changing distance between the curved surface 402 to the facing substrate support assembly 130.

The choke 450 has a first bore 406, 408 and a second bore 410, 412 formed in the plate 400. As the plate 400 is deformed to make the downstream surface 418 into the curved surface 402, the size, shape, and configuration of the chokes 450 formed in the plate 400 may be changed by the forming process as well. Additionally, as the upper surface 420 of the plate 400 is machined, a portion of the first bores 406 located in the center of the edge portion 430 of the plate 400 is removed, thereby making the length of the first bore 406 in the center of the edge portion 430 of the plate 400 shorter than the length of the first bore 408 disposed in the corner portion 408. Additionally, the deformation of the second bores 410, 412 in the concave surface 402 created by the bending process may also make the second bores 412, 410 have tapered inner walls and different cavities profiles. As the second bores 412, 410 have different cavities profiles, a hollow cathode effect and/or hollow cathode gradient (HCG) is thereby generated which causes a gradient in plasma uniformity across the substrate surface. By a well predefined and calculated machining and/or bending process, the depths, distributions, shapes, and densities of the chokes may be selected to create a desired gas and/or plasma distribution across the surface of the substrate positioned on the substrate support assembly 130, thereby depositing a film on the substrate surface with desired thickness profile and film properties.

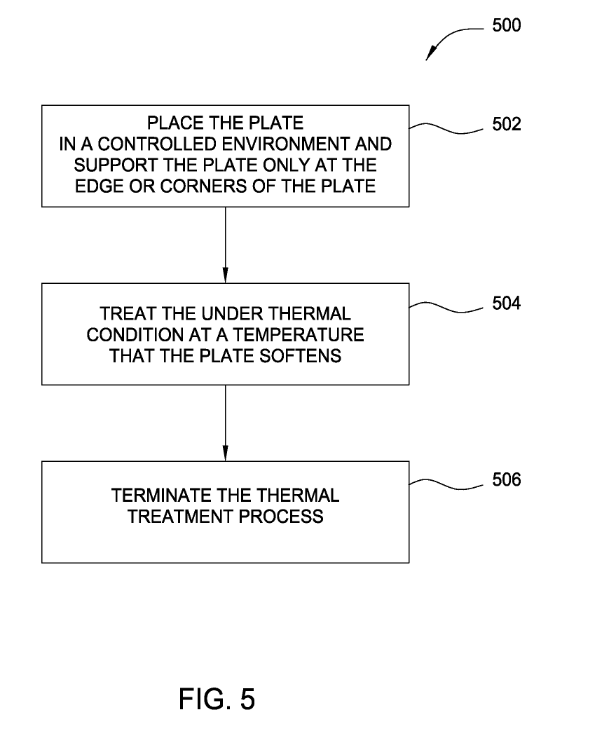

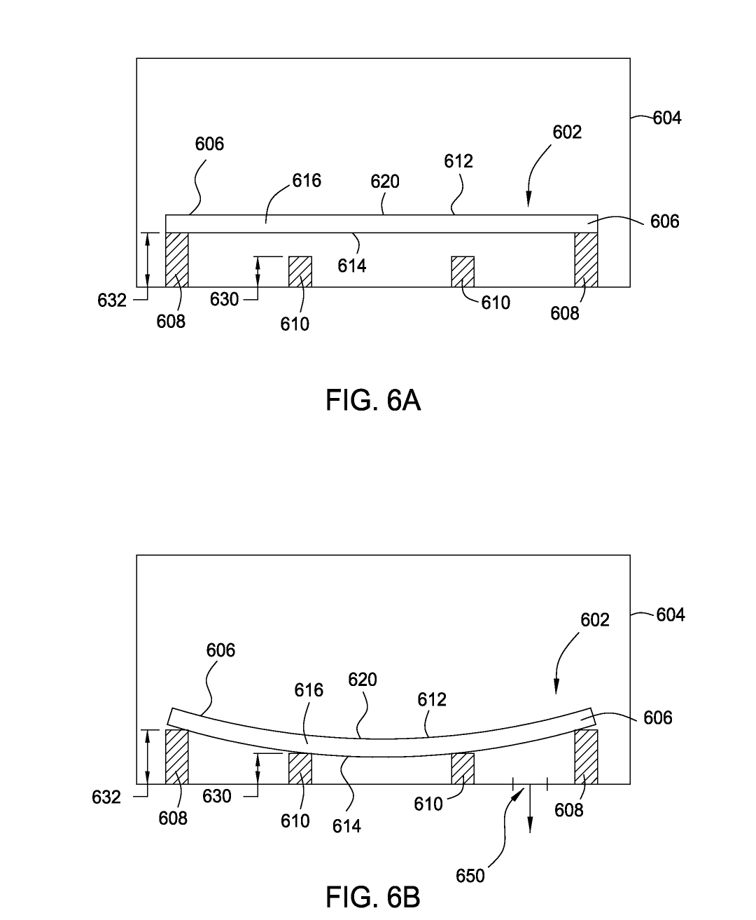

FIG. 5 depicts a process flow 500 of one embodiment of a thermal treatment process for manufacturing a gas distribution plate having a curved surface. FIGS. 6A-B depict different stages for manufacturing a gas distribution plate having different chokes lengths using the thermal treatment process 500 as described in FIG. 5.

The process 500 starts at step 502 by placing a substantially planar gas distribution plate 602 over a plurality of outer supports 608 and inner supports 610 disposed in an environment 604. An edge portion 606 of the plate 602 is initially positioned on the outer support 608 while the inner supports 610 are spaced from the plate 602, as shown in FIG. 6A. Optionally, the outer supports may only support the corners of the plate 602. The inner support 610 and the outer support 608 may be fabricated from a material suitable for use at a temperature greater than 500 degrees Celsius. The outer supports 608 have a greater height 632 than the height 630 of the inner support 610. As the plate 602 is positioned on the outer support 608 by its edge portion 606, the center portion 616 of the plate 602 is suspended above the inner supports 610. The difference between the heights 632, 630 of the inner support 610 and the outer support 608 may be selected to produce a desired curvature of the plate 602 after the thermal treatment process 500 is completed. Alternatively, the location of the inner support 610 in the environment may be selected to control the curvature of the plate 602. For example, inner supports 610 positioned closer to the center line 620 of the plate 602 may result in less plate curvature as compared to inner supports 510 (of the same height) positioned closer to the edge portion 606 of the plate 602. In an exemplary embodiment, the height of the inner support 610 and the outer support 608 may be selected to produce a plate having a chord depth between about 0.05 inch and 1 inch.

The environment 604 in which the process 500 may be performed may be a chamber, a furnace, a canister, or any other type of environment suitable for performing the thermal process. In one embodiment, the chokes may be formed through the plate 602 before performing the thermal treatment process 500. In another embodiment, the chokes may be formed after the thermal treatment process 500 has been performed. The sequence of the drilling and thermal treatment process may be performed in any order.

In one embodiment, the upper surface 612 of the plate 602 may face the backing plate 112 when used in the chamber 100. The lower surface 614 of the plate 602 may face the substrate support assembly 130 upon installation in the chamber 100. Alternatively, the upstream and downstream sides may be switched to have the convex surface facing the backing plate 112.

At step 504, the temperature in the environment 604 is raised and maintained, for example between about 400 degrees Celsius and about 600 degrees Celsius, to soften the gas distribution plate 602. In one embodiment, the temperature may be gradually ramped up until the desired temperature, such as about every 2 to 5 seconds for 10 degree Celsius, until the desired temperature is reached.

After thermal processing for a period of time, the plate 602 begins to soften and sag, as shown in FIG. 6B. As the plate 602 softens, gravity pulls the center portion 616 of the plate 602 downwardly until the plate 602 contacts the upper surface of the lower inner support 610. As the inner support 610 and the outer support 608 have a predetermined height difference, a predefined curvature is set in the plate 602. It is also contemplated that vacuum or other mechanic force may be applied to the plate 602 to assist in obtaining a desired plate curvature.

Once the curvature of the plate 602 has been reached, the thermal treatment process 500 is terminated at step 506. In some embodiments, the inner support 610 may be eliminated and the plate 602 may be curved until reaching the bottom surface of the environment 604 or the limit of plate's physical deformation for the conditions within the environment 604.

Alternatively, the curvature of the plate 602 may be formed by a bending process in a vacuum environment or by application of a mechanical force. A pumping channel (shown in phantom 650 at FIG. 6B) may be provided in the environment and used to pull vacuum in one region of the environment 604. The pressure differential across the plate 602 causes the plate 602 to curve. The plate 602 may be supported in the vacuum environment by the supports 610, 608. After a desired curvature of the plate is reached, the vacuum is released to remove the plate from the environment. Examples of a suitable vacuum bending process and the thermal treatment process that may be adapted to benefit from the invention are disclosed in U.S. Patent Publication No. 2005/0251990 published on Nov. 17, 2005 to Choi et al, which is incorporated by reference in their entirety.

After the plate 602 is curved, the upper surface 612 may be used as the upper surface of the plate 602. The curved lower surface 614 of the plate 602 may be used as a downstream surface, or be machined flat.

FIG. 7 depicts another embodiment of a gas distribution plate 702 having chokes 706 that produces a flow gradient between the edge and corner of the plate 702. The gas distribution plate 702 has a plurality of chokes 706 formed therethrough. In one embodiment, the chokes 706 may be formed in the plate 702 by a computer numerically controlled (CNC) machining. The distribution and configuration of individual chokes 706 may be selected to produce a corner to edge gradient of gas flow exiting the plate 702.

Each choke 706 includes a bore 708 (shown as 708C in a center portion 728 of the plate 702 and 708E in a corner portion 726) coupled to a passage 710 (shown as 710C and 710E in the edge portion 728 and corner portion 726 of the plate 702 respectively). The passages 710C, 710E and the bores 708C, 708E collectively form a fluid path that allows gas from the gas source 120 to pass through the plate 702 and enter the process region 106 above the substrate support assembly 130. The passages 710C, 710E have upper openings 730C, 730E formed in the upper side 732 of the gas distribution plate 702. The diameters of the passages 710C, 710E and the bores 708C, 708E may be selected to control a desired amount of gas flowing therethrough. In one embodiment, passages 710C, 710E have a smaller diameter than that of the bores 708C, 708E. Alternatively, the diameters of the passages 710C, 710E and bores 708C, 708E may be configured in any other different configurations.

The passages 710C, 710E have a first depth 724, 716 extending from the upper opening 730C, 730E to a lower opening 736C, 736E. The lower opening 736C, 736E couples to an upper opening 740C, 740E of the bore 708C, 708E. The bore 708C, 708E has a second depth 720, 718 extending from the upper opening 740C, 740E to a lower opening 744C, 744E formed on a downstream surface 748 of the gas distribution plate 702.

The chokes 706 located in the center of the edge portion 728 of the plate 702 and in the corner portion 726 may have different depths of the passages 710C, 710E and the bores 708C, 708E which create an edge to corner flow gradient at the edge of the plate 702. In one embodiment, the chokes 706 located in the edge portion 728 have a shorter first depth 724 and a longer second depth 720 than the first depth 716 and the second depth 718 located in the corner portion 726. The depth difference and variation between the passages 710C, 710E and the bores 708C, 708E located in the edge and corner portions 726, 728 of the plate 702 may be designed and configured to control the amount of gases flowing through the corner of plate 702 relative to the edges of the plate 702, thereby creating flow gradient across the substrate surface 118. In one embodiment, the upper surface 732 configured to face the backing plate 112 and the downstream surface 748 configured to face the substrate support assembly 130 may have flat surfaces. As the upper 732 and the downstream surface 748 are planar, the width 750 across the plate 702 may determine the total depth including the first depth 724, 716 and the second depth 720, 718 across the plate 702 (e.g., including the area of the edge portion 728 and center portion 726 of the plate 702).

In the embodiment depicted in FIG. 7, the first depth 724 located in the edge portion 728 of the plate 702 may be shorter than the first depth 716 in the corner portion 726 between about 0.05 inch and about 1 inch. The length and/or dimension difference of the passages 710C, 710E and bores 708C, 708E located between the edge portion 728 and the corner portion 726 may carry different amount of gases from the gas source 120 across the substrate surface 118. For example, the longer first depth 716 of the first bore 710E located at the corner portion 726 may create higher restrictive flow (e.g., more resistance) within the inner side of the bore 708E, thereby efficiently allowing the film properties deposited on the substrate being adjusted. In the embodiment where the diffuser plate 702 is utilized to deposit a silicon film, restricting the flow of the gases at the corner portion 726 relative to the flow through the edge 728 results in higher crystalline volumes in the corners of the deposited silicon film compared to conventional processes, along with increased film property converts edge uniformity, such as improved crystal fraction ratio uniformity in the corners and edges of the substrate.

In an embodiment where a film is generally deposited as a dome-shape film profile and/or non-uniform film properties in conventional deposition process (e.g., a film profile and properties having an edge portion thicker and/or different than a corner edge portion), a shorter first depth 724 of bore 710C located in the edge portion 728, as shown in FIG. 7, may be utilized to have lower gas restrictive flow generated in the edge portion 728 than the restrictive flow generated in the corner portion 726, thereby tuning the film properties, and profile formed on the substrate 140, or vise versa.

FIG. 8 depicts a cross sectional view of another embodiment of a gas distribution plate 802 having different configuration of chokes 810 formed therein. Similar as the chokes 706 in FIG. 7, the chokes 810 through the plate 802 includes a bore (shown as 814C in a center of an edge portion 804 of the plate 802 and 814E in a corner portion 806) coupled to a passage (shown as 808C in the edge portion 804 of the plate 802 and 808E in the corner portion 806). The passages 808C, 808E and the bores 814C, 814E collectively form fluid paths that allow the gas from the gas source 120 to pass through the plate 802 to the upper surface 132 of the substrate support assembly 130. The passages 808C, 808E has an upper opening 826, 828 formed in the upper side 830 of the gas distribution plate 802. The passages 808C, 808E has a first depth 818, 822 extending from the upper opening 826, 828 to a lower opening 834 (shown as 834C in the edge portion 804 of the plate 802 and 834E in the corner portion 806). The lower openings 834C, 834E of the passages 808C, 808E couples to the bores 814C, 814E having a flared-out opening 838, 840 formed on the downstream surface 832 of the plate 802. The bores 814C, 814E have a second depth 820, 824 extending from the lower openings 834C, 834E to the flared-out opening 838, 840.

Similar to the description above of FIG. 7, the passages 808C, 808E and the bores 814C, 814E formed in the plate 802 may have different dimensions, configurations, depth, and lengths to meet different process requirements. In the embodiment depicted in FIG. 8, the bores 814C, 814E formed in the edge portion 804 and corner portion 806 of the plate 802 have different depth 820, 824, thereby forming different inner volume and/or cavity within the bores 814C, 814E. The bore 808C located in the edge portion 804 has a shorter first depth 818, thereby forming a larger inner volume and/or cavity within the bore 814C, as compared to the bore 814E located in the center portion 806. The shorter first depth 818 of the bore 808C provides lower restrictive flow, thereby eliminating reaction occurred adjacent the edge portion 804 of the plate 802, resulting in adjusting different film properties formed therein. The different configuration of the chokes formed in the plate may provide different flow gradient across the substrate surface, thereby efficiently adjusting the film profile, properties, uniformity of the film properties and thickness deposited on the substrate surface. In embodiments where hollow cathode effect and/or hollow cathode gradient are desired to be formed in the chokes 810, the diameter 850 of the chokes 810 formed across the downstream surface 832 of the plate 802 may be selected to provide desired hollow cathode effect and/or hollow cathode gradient.

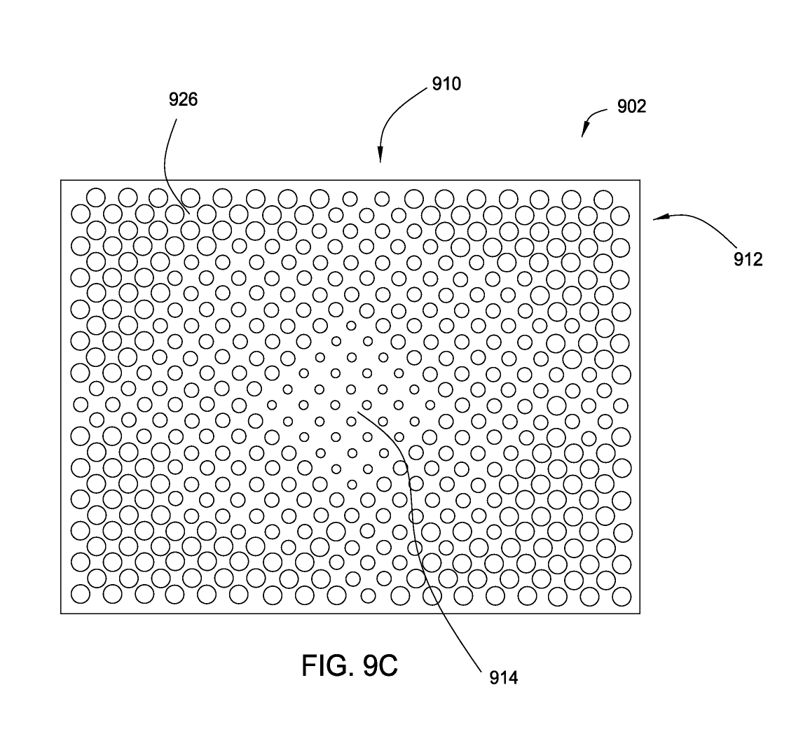

FIGS. 9A-C depict another embodiment of a gas distribution plate 902 having a plurality of chokes 926 that provides flow gradient when gases are passed therethrough. The chokes 926 formed in the plate 902 may have identical depth of passages (shown as 914C in a center of an edge portion 910 of the plate 902 and 914E in a corner portion 912) and bores (shown as 918C in the edge portion 910 of the plate 902 and 918E in the corner portion 912) across the plate 902, as shown in FIG. 9A. However, the diameters 906, 904, 908 of the bores 918C, 918E may be varied on the downstream surface 928 of the plate 902 to provide a different distribution of gas flowing to the substrate surface. As the dimensions of the bores 918C, 918E are different, a hollow cathode gradient (HCG) is provided across the substrate surface. In another embodiment, an upper surface 930 of the plate 902 may be machined to form a concave surface 932 having the edge portion 910 of the plate 902 thinner than the corner portion 912, as shown in FIG. 9B. The concave surface 932 removes a portion of the passages 914 from the plate 902, resulting in the passage 914C in the edge portion 910 having a shorter depth 934 and less flow resistance than the passage 914E in the corner portion 912. As the passage 914C in the edge portion 910 has less flow resistance as opposed to the higher flow resistance in the passage 914E in the corner portion 912, a flow gradient across the plate 902 is generated by gas flow resistance difference and the film properties deposited on the substrate may be efficiently adjusted. For example, in embodiments where a silicon film deposited by conventional manners having a low crystalline volume in the edge portion, the plate 902 having a higher flow resistance in the passage 914E of the corner portion 912 (e.g., the passage 914E with longer length than passage 914C), as shown in FIG. 9B, may be utilized to deposit the silicon film to have a higher crystalline volume and more uniform crystal fraction ratio at the corners, thereby compensating and adjusting the film properties difference formed thereof. As the different dimensions of the bores 918C, 918E are formed on the downstream surface 928 to provide hollow cathode gradient (HCG), a combined effect of hollow cathode gradient (HCG) and flow gradient (e.g., gas flow resistance difference) may be generated in the plate 902 of FIG. 9B.

FIG. 9C depicts a bottom view of the downstream surface 928 of the plate 902 having chokes 926 opened thereon. The surface area density and distribution of the chokes 926 formed on the plate 902 may be varied to meet different process requirement. In one embodiment, the chokes 926 in the corner edge portion 912 may have a higher surface area density than chokes 926 in the center portion 910 in the plate 902 so that a hollow cathode gradient (HCG) may be provided. In contrast, the distribution, densities, numbers, shape, and dimensions of the chokes 926 may be formed in many alternative configurations through the plate 902. Optionally, the center 914 of the plate 902 may include few chokes 926 per unit area than the edge portion 910 or corner portion 912. Conversely, the choke density may increase from corner to edge to center.

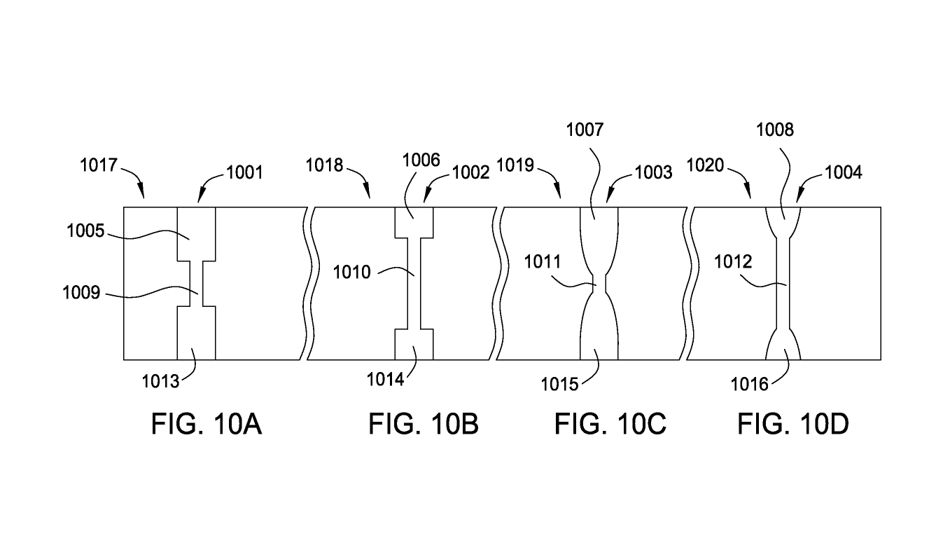

FIGS. 10A-D depict different embodiments of chokes 1001-1004 formed in plates 1017-1020 that produce a flow gradient of passing through the plates. In one embodiment, the chokes 1001-1004 may be formed in the plates 1017-1020 by a computer numerically controlled (CNC) machining. The chokes 1001-1004 generally include a first bore 1005-1008 and a second bore 1013-1016 connected by an orifice 1009-1012. The first bores 1005-1008 are formed on the upper portion of the plates 1017-1020 and the second bores 1013-1016 are formed on the lower portion of the plates 1017-1020. The first bores 1005-1008 and the second bores 1013-1016 are coupled by the orifices 1009-1012 to collectively fluid flow passages through in the plates 1017-1020. The first bores 1005-1008 and the second bores 1013-1016 may each have different configurations, dimensions, shape, size, numbers, and distributions formed across the plates 1017-1020, thereby carrying different amounts and/or having different flow rates of process gases flowing through the plates 1017-1020 to the substrate surface. Different amounts and/or flow rates of process gases create flow gradient across the substrate surface, thereby facilitating profile and/or property control of films deposited on the substrate surface.

In one embodiment, the depth and/or length of the orifices 1009-1012 may be different in combination with different configurations of the first 1005-1008 and the second bores 1013-1016. By adjusting the flow gradient created by different configuration of the chokes 1001-1004, the film thickness and the profile deposited on the substrate surface may be accordingly controlled.

In one embodiment, the first 1005-1008 and the second bores 1013-1016 may have different configurations, such as square shapes 1005-1006, 1013-1014 with different depth of the orifices 1009-1010, cone shapes 1015-1019, 1007-1008 with different depths of the orifices 1011-1012, and the like. The depth of the bores 1005-1008, 1013-1016 may be varied to meet different process requirements.

The opening of the second bores 1013-1016 may be flared out at a desired angle or have a diameter within a desired range, thereby assisting the distribution of the process gases across the substrate surface. The configuration of the second bores 1002 may be controlled in a manner that may or may not create a hollow cathode effect therein. Alternatively, the configuration of the second bore 1013-1016 may be controlled in any manner.

In one embodiment, the diameter of the second bores 1013-1016 may be selected at a range between about 0.05 inch and about 0.5 inch so that the plasma may dwell in the second bores 1013-1016, thereby creating hollow cathode effect. In some embodiments where hollow cathode effect may not be desired, the diameter of the second bores 1013-1016 may be selected at a range greater than about 0.01 inch or smaller than about 0.05 inch to prevent the electron oscillation in the second bores 1013-1016, thereby preventing the hollow cathode effect from being created in the second bores 1013-1016 during processing.

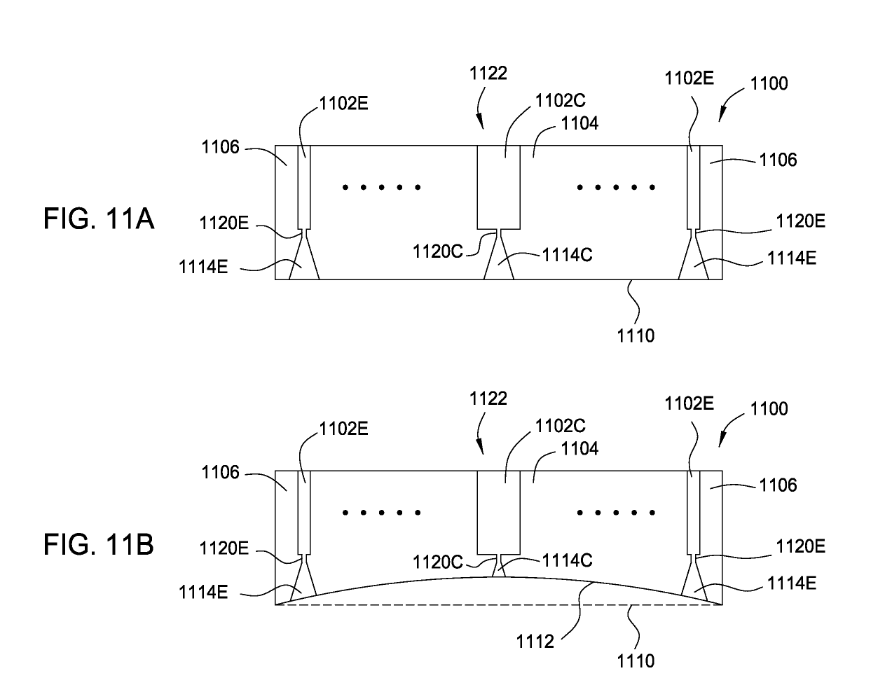

FIGS. 11A-B depict cross sectional views of a gas distribution plate 1100 at different stages of a process flow for manufacturing the gas distribution plate 1100. A plurality of chokes 1122 may be formed through the plate 1100, as shown in FIG. 11A. The entire chokes formed across the plate 1100 are not depicted in the FIGS. 11A-B but only a representative choke formed in the center portion 1104 and some chokes formed in the edge portion 1106 are present for sake of clarity. The chokes 1122 include a passage (shown as 1102C in the center of an edge portion 1104 and shown as 1102E in the corner portion 1106) and a bore (shown as 1114C in the edge portion 1104 and shown as 1114E in the corner portion 1106) coupled by an orifice (shown as 1120C in the edge portion 1104 and shown as 1120E in the corner portion 1106). The bores 1114C, 1114E have an opening formed on a downstream surface 1110 of the plate 1100 configured to face the substrate support assembly 130. In one embodiment, the bores 1114C, 1114E and the orifices 1120C, 1120E formed in the plate 1100 may be identical. The passages 1102E formed in the edge portion 1106 of the plate 1100 may have a narrower diameter than the passages 1102C formed in the center portion 1104 to provide a high flow resistance in the edge portion 1106 of the plate 1100. The dimension difference between the passages 1102C, 1102E in the plate 1100 provides a manner to generate flow gradient therethrough, thereby efficiently adjusting the film properties and/or profile deposited on the substrate. It is noted that the major flow resistance may be created by different dimensions selected for the first passages 1102C, 1102E or for the orifices, 1120C, 1120E. In embodiments where the major flow resistance is created by the selected dimensions of the orifices 1120C, 1120E instead of the first passages 1102C, 1102E, the dimension difference of the first passages 1102C, 1102E formed on the plate 1100 may not be efficiently generated flow gradient for the gases supplying therethrough. Additionally, a portion of the downstream surface 1110 formed in the plate 1100 may be machined out to create a concave surface 1112, as shown in FIG. 11B. The concave surface 1112 results in the bores 1114C, 1114E formed thereof in different configurations thereof, thereby generating the hollow cathode gradient (HCG). It is noted that the concave surface 1112 also provides a spacing gradient toward the substrate positioned on the substrate support assembly 130 upon installing the plate 1100 into the processing chamber 100. Accordingly, a combination of flow gradient, the hollow cathode gradient (HCG) and/or the spacing gradient between the plate 1100 and the substrate support assembly 130 may be obtained by controlling the dimensions of the passages 1102C, 1102E, the bores 1114C, 1114E and the curved surface formed on the downstream surface 1110.

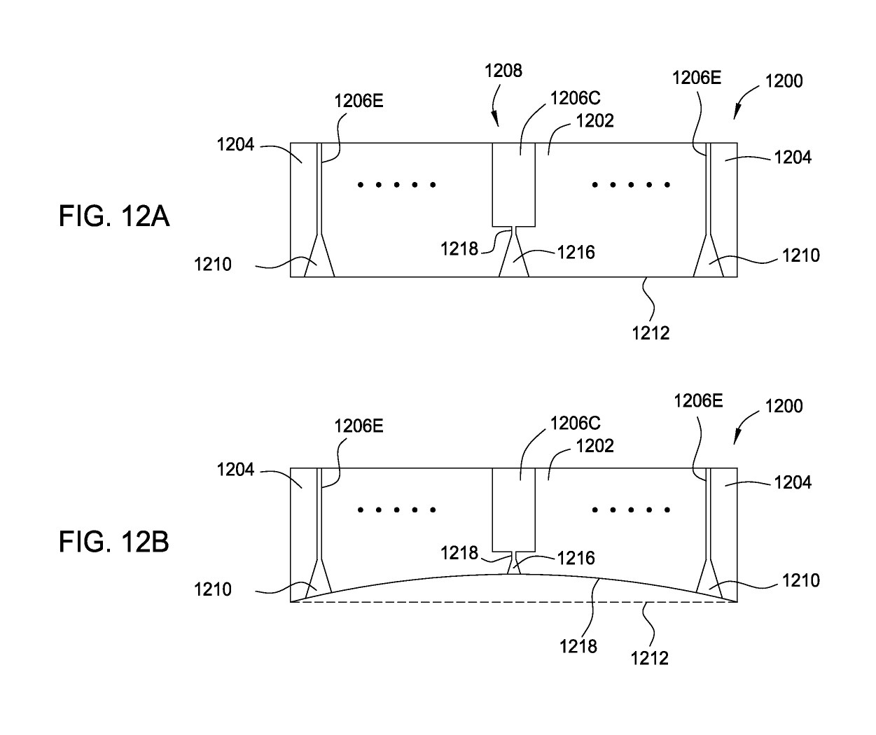

FIGS. 12A-B depict cross sectional views of another embodiment of a gas distribution plate 1200 having different choke configurations formed in an edge portion 1202 and a corner portion 1204 of the plate 1200. In the embodiment depicted in FIG. 12A, the choke 1208 located in the edge portion 1202 may have a passage 1206C coupled to a bore 1216 by an orifice 1218, as the choke 1122 depicted in FIG. 11. As for the choke 1208 formed in the corner portion 1204, the choke 1208 may has a longer passage 1206E coupled to a bore 1210 having an opening formed on a downstream surface 1212 formed in the plate 1200. The longer passage 1206E provides a higher flow resistance than the passage 1206C formed in the center portion 1202, thereby providing an edge to corner flow gradient across the plate 1200. Optionally, a portion of the downstream surface 1212 formed in the plate 1200 may be machined out to create a concave surface 1214, as shown in FIG. 12B. Similar to the designs in FIG. 11B, the concave surface 1214 provides a hollow cathode gradient (HCG) and a spacing gradient upon installing to the chamber 100.

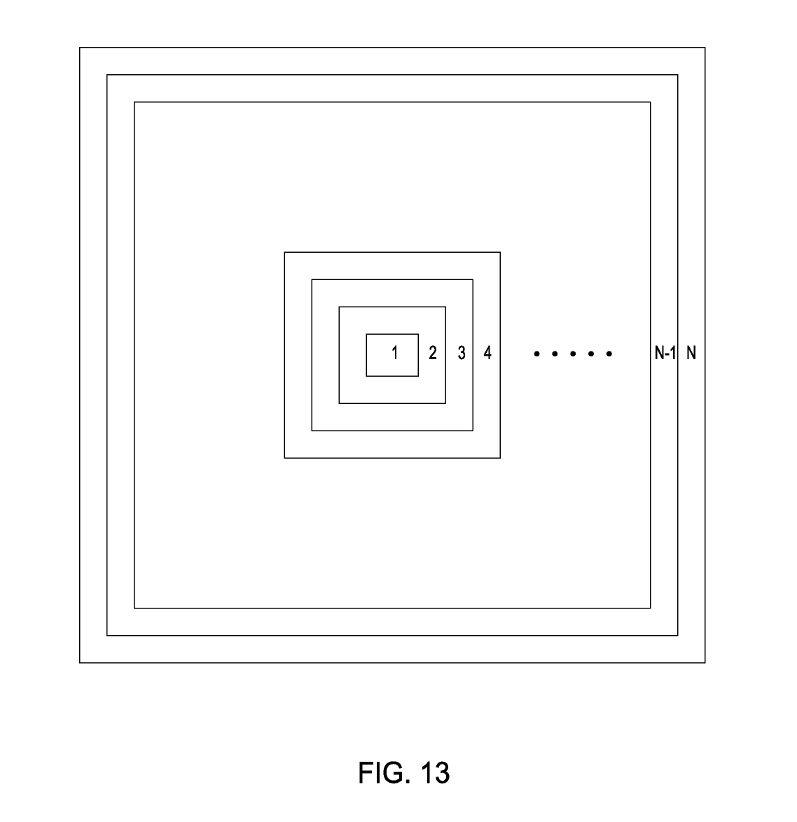

FIG. 13 depicts a schematic plot of a bottom view of a gas distribution plate. The plate is divided into N concentric zones. Within each zone, the chokes may or may not be identical. Zones may be polygonal rings, such as square, rectangular or circular ring. From zone 1 to zone N, the chokes formed through the plate may have gradually increased flow resistance (e.g., longer and/or more restrictive choke geometric choke length). Alternatively, the hollow cathode cavities formed in the chokes may gradually increase in size (volume and/or surface area). The increase of the flow resistance and hollow cathode cavities may be achieved by different choke diameter, length, flaring angle, or a combination of these parameters, as depicted in connection to the Figures depicted above.

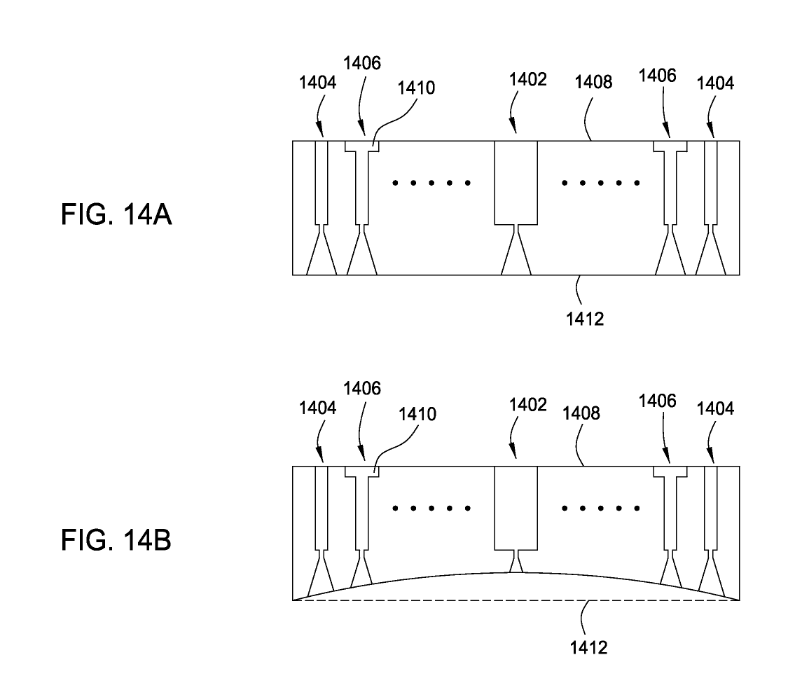

FIG. 14A-B depicts an exemplary embodiment of a cross sectional view of a plate having different choke configurations formed in different zones of the plate, as discussed in FIG. 13. In the embodiment depicted in FIG. 14A, the choke 1402 formed in the center zone, such as zone 1 in FIG. 13, may have a wider dimension as compared to the chokes 1404 formed in the corner of an edge zone, such as the corner of zone N in FIG. 13. Additionally, chokes 1406 with different configurations, such as having a bore 1410 formed on the upper portion of the choke 1406 having an opening formed on the upper surface 1408 of the plate, may be formed within the same zone, such as edge zone N in FIG. 13, where the choke 1404 is located. It is noted that each zone may have as many as different choke configurations to provide different center to corner flow gradient. Furthermore, a portion of the plate on the downstream surface 1412 may be machined out to generate hollow cathode gradient (HCG) and a spacing gradient upon installing to the chamber 100.

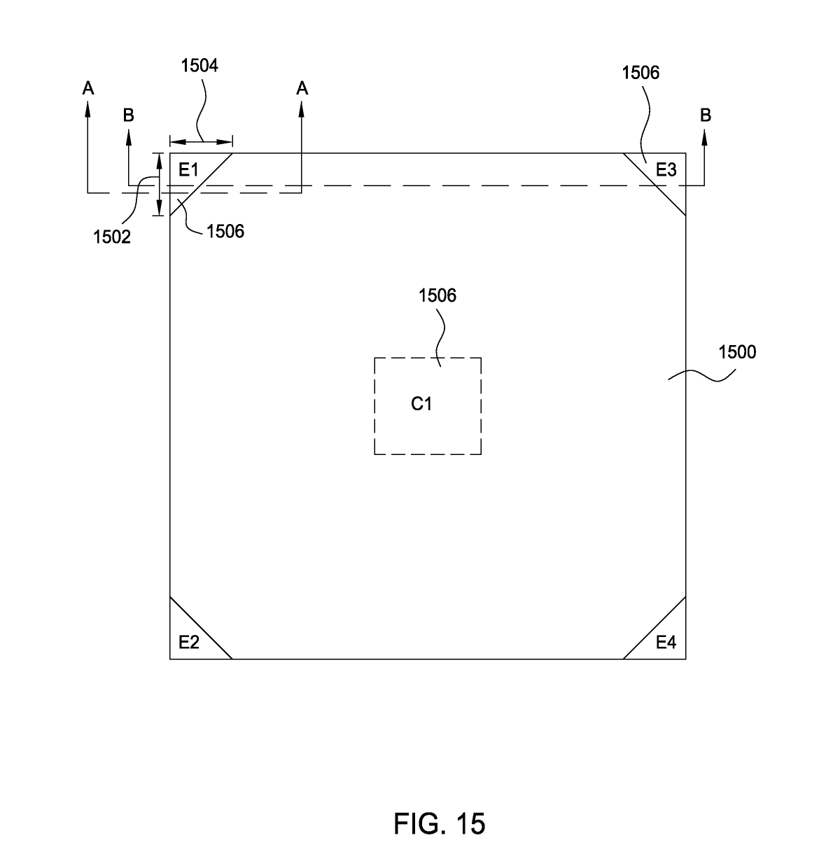

FIG. 15 depicts another embodiment of a top view of a gas distribution plate 1500. The gas distribution plate 1500 has at least four corns E1-E4 separated by four sides of the plate 1500. As the downstream surface of the plate 1500 may be curved as discussed above, the chokes formed through the corners E1-E4, in a center zone C1, and along the edge of the four sides of the plate 1500 may have different choke lengths. In one embodiment, a first plurality of chokes formed through the corners E1-E4 of the plate 1500 have longer choke lengths than a second plurality of chokes formed through the edge along the side of the plate 1500 between corners E1-E4. Additionally, a third plurality of chokes may be formed in the center zone C1 of the plate 1500 and/or formed inward than the locations where the first and the second plurality of chokes are formed. The third plurality of chokes have shorter choke lengths than the chokes formed through the corners E1-E4 and the edges along the sides of the plate 1500 between corners E1-E4. As the first plurality of chokes formed in the corners E1-E4 have longer lengths, a higher flow resistance is encountered through the first plurality of the corner chokes of the plate 1500 relative to the flow resistance encountered through the second and third plurality of chokes. Additionally, as the second plurality of chokes may have longer lengths than the third plurality of chokes but shorter lengths than the first plurality of chokes, the flow resistance encountered through the second plurality of chokes is greater than the flow resistance encountered through the third plurality of chokes but less than the flow resistance formed in the first plurality of chokes.

Alternatively, an adaptor plate 1506 may be utilized on the upper side and/or bottom side of the plate 1500. In the embodiment where the adaptor plate 1506 is used, the downstream surface of the plate 1500 may be curved or remain flat. The adaptor plate 1506 has a plurality of chokes formed therein that align with the chokes formed in the plate 1500 to control the flow resistance through the corners of the plate 1500. The adaptor plate 1506 may be configured in any different sizes, shapes or dimensions accommodated to increase the choke length at a certain desired zone in the plate 1500. In the embodiment depicted in FIG. 15, the adaptor plate 1506 may be positioned at four corners E1-4 of the plate 1500 to provide increased flow resistance through the corners of the plate 1500. The adaptor plate 1506 may be in form of a triangular shape having two sizes attached to the corners E1-4 of the plate 1500. In one embodiment, the adaptor plate 1506 has an equilateral triangular shape having length 1502 between about 50 mm and about 1000 mm, such as about 500 mm. Alternatively, the adaptor plate 1506 may be positioned in any other different zones on the plate 1500. For example, the adaptor plate 1506 may be positioned at the center zone C1 of the plate.

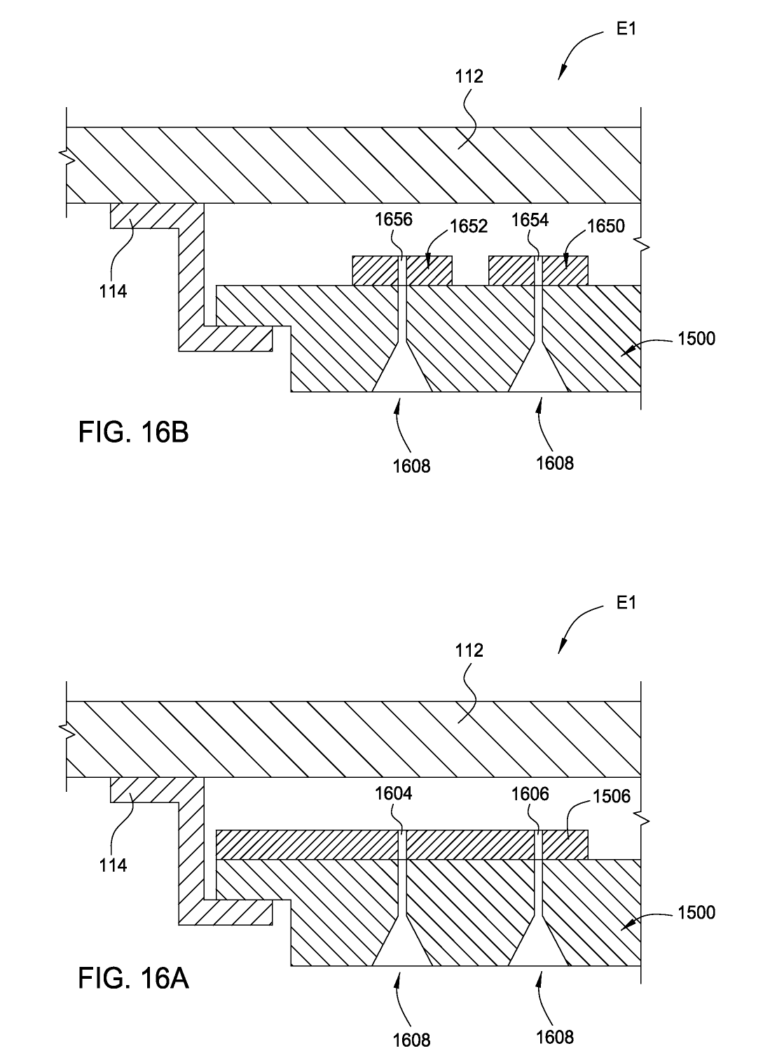

FIGS. 16A-B depict a cross sectional view of the gas distribution plate 1500 of FIG. 15 taken along with the line A-A upon installation in the chamber 100. In the embodiment depicted in FIG. 16A, the adapter plate 1506 may be in form of a blank piece having a plurality of chokes 1604, 1606 formed therein. The chokes 1604, 1606 formed in the adapter plate 1506 are aligned with the chokes 1608 formed in the plate 110. The aligned chokes 1604, 1606 in the adapter plate 1506 increase the overall length of the chokes 1608 where the process gas may flow through from the gas source 120, thereby creating a higher gas flow resistance at the area where the adaptor plate 1506 is located. By using the adaptor plate 1506, the total length of the choke 1608 where the process gas may flow through may be flexibly adjusted, thereby providing a manner to adjust a deposited film properties and/or profile located at a certain spot. Alternatively, the adaptor plate 1506 may be segmented into several pieces 1650, 1652 as shown in FIG. 16B to increase the length of a certain choke 1608 selected in the plate 110.

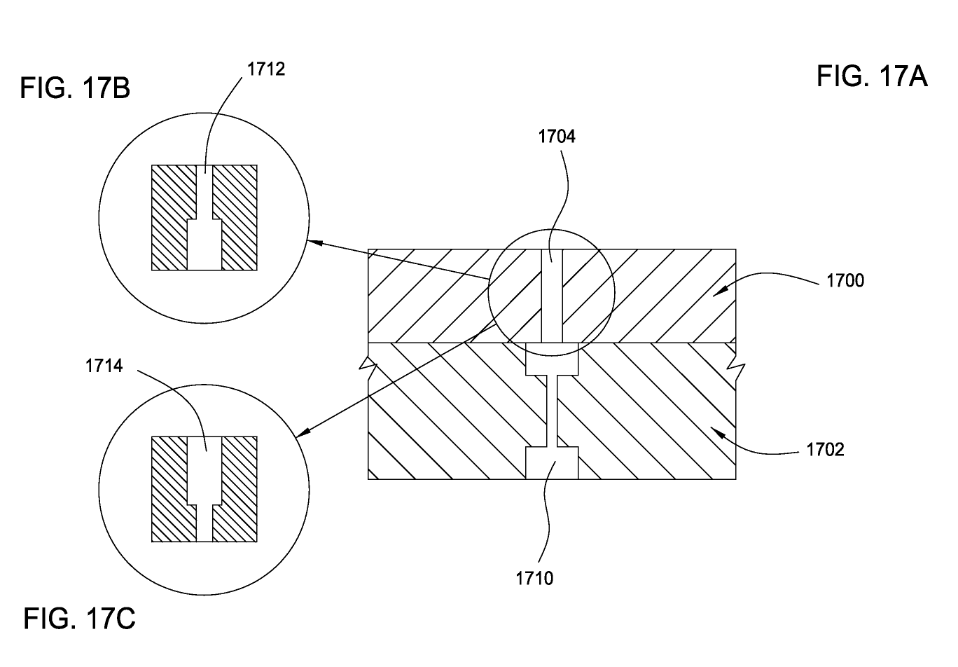

FIGS. 17A-17C depict different embodiments of an adaptor plate 1700 that may have different choke configurations formed therein. In embodiment depicted in FIG. 17A, the chokes 1704 formed in the adaptor plate 1700 are straight holes. The adaptor plate 1700 is mounted to a gas distribution plate 1702 having chokes 1710 formed therein. The chokes 1710 may be in any different shapes, dimensions and configurations as needed. Alternatively, the choke 1704 formed in the adaptor plate 1700 may have different configurations, such as a upper narrower passage coupled to a lower wider bore, as shown in FIG. 17B, or an upper wider passage coupled to a lower narrower bore, as shown in FIG. 17C.

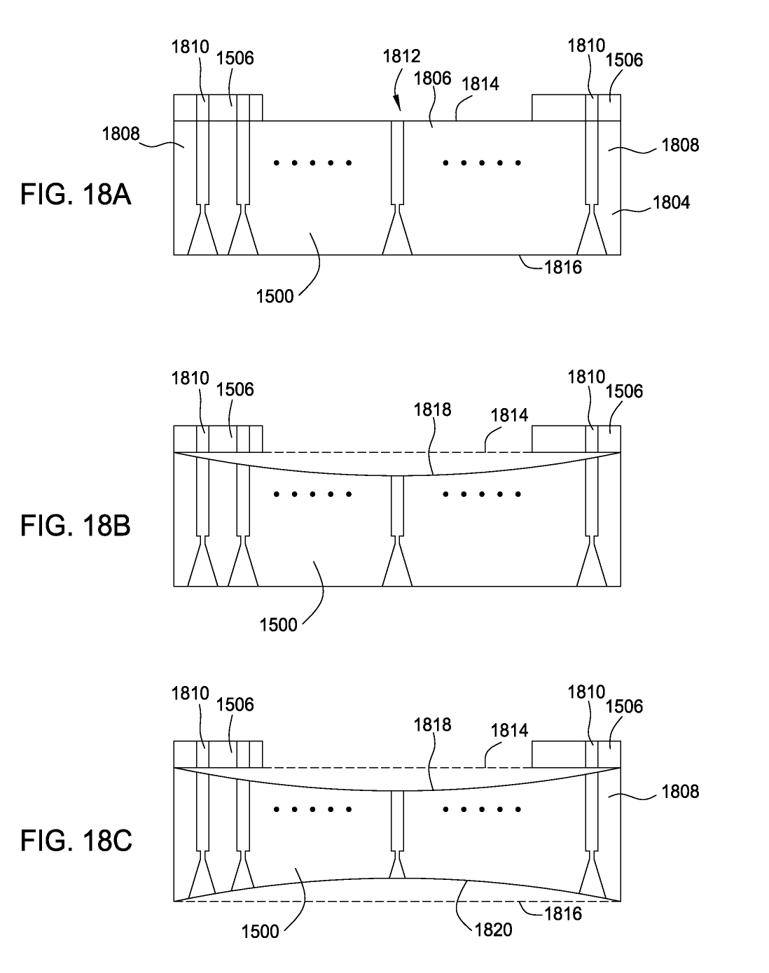

FIGS. 18A-C depict a cross sectional view of different embodiments of the gas distribution plate 1500 of FIG. 15 taken along with the line B—B upon installation in the chamber 100. In the embodiment depicted in FIG. 18A, the adaptor plate 1506 is attached to an upper surface 1814 of the plate 1500. The adaptor plate 1506 is selectively located in the corner portion E1, E3, e.g., a corner portion 1808, of the plate 1500. Chokes 1810 formed in the adaptor plate 1506 are aligned with the chokes 1812 formed in the plate 1500 to increase the overall flow resistance of process gases provided from the gas source 120 flowing through the corner portion 1808 of the plate 1500. Alternatively, a portion from the upper surface 1814 of the plate 1500 may be machined out to create a curved upper surface 1818, thereby resulting the chokes 1812 located in the edge and/or center portion 1806 having a shorter length than the chokes 1812 located at corner portion 1808, as shown in FIG. 18B. It is noted that the curvature of upper surface 1818 at the edge portion where the adaptor plate 1506 located is exaggerated for sake of clarity. Optionally, a portion from the downstream surface 1816 of the plate 1500 may be machined out to create a curved lower surface 1820, resulting the chokes 1812 having different cavities and/or flared-out dimensions, thereby creating hollow cathode gradient (HCG). Additionally, as discussed above, the curved lower surface 1820 also creates a spacing gradient to the facing substrate support assembly 130 upon installing into the chamber 100.

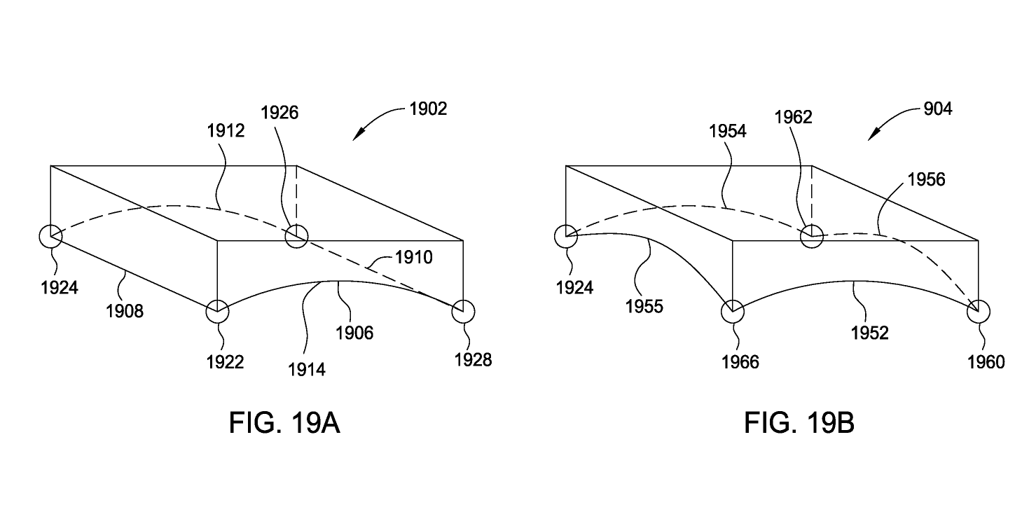

Referring additionally to one embodiment of a gas distribution plate 1902 depicted in FIG. 19A, the gas distribution plate 1902 has a perimeter that includes corners 1922, 1924, 1926, 1928 and edges 1906, 1908, 1910, 1912. It is noted that the apertures formed through the plate 1902 are not depicted for sake of clarity. A center 1914 of the edge 1906 of the plate 1902 is spaced further away from the substrate support assembly 130 than the edges 1908, 1910 and corners 1922, 1924, 1926, 1928 of the plate 1902. The apertures through the corners 1922, 1924, 1926, 1928 have longer lengths as compared to apertures formed through the center 1914 of the edge 1906, and thus have a great flow conductance so that more process gas is delivered through the plate 1902 through to the center 1914 of the edge 1906 relative to the flows through the corners 1912, 1914, 1926, 1928. It has been discovered than when depositing polysilicon utilizing a plasma enhanced CVD process, increased crystal volume and fraction uniformity is obtained utilizing gas distribution plates having edge to center spacing gradients as compared to gas distribution plates having uniform spacing around the perimeter of the plate. Although the embodiment depicted in FIG. 19A illustrates an edge to corner spacing gradient defined on only two edges of the plate 1902, FIG. 9B illustrates another embodiment of a gas distribution plate 1904 which has spacing gradients defined along each of the four edges 1950, 1952, 1954, 1956 compared to the corners 1960, 1962, 1964, 1966. Additionally, although the gas distribution plates 1902, 1904 are shown with the spacing gradients facing the substrate with a flat side of the distribution plates 1902, 1904 facing upward, it is contemplated that the flat side of the gas distribution plates 1902, 1904 may be oriented toward the substrate or that both sides of the gas distribution plates 1902, 1904 may include edge to corner spacing gradients.

In an exemplary embodiment suitable for deposition a silicon film for solar cell applications, the deposition process may be configured to deposit a microcrystalline layer using a flow gradient producing plate. The microcrystalline layer may be an i-type layer formed in a p-i-n junction for solar cell devices. Alternatively, the microcrystalline layer may be utilized to form other devices. The gas distribution assembly may have different configurations (e.g., dimension, depth, and the like) of chokes formed therein to create an edge to corner flow gradient with or without a hollow cathode effect upon supplying gases through the distribution plate. The flow gradient may be created using at least one of an upper concave surface on an upper surface of the gas distribution plate, or a gas distribution plate having chokes configured with different depths and/or length across the plate such that the resulting gas flow is different at the corners of a gas distribution plate relative to the edges of the gas distribution plate. In a particular embodiment depicted in the present invention, the gas distribution plate provides a higher gas flow resistance in a corner portion of the gas distribution plate than the gas flow resistance in a center of an edge portion of the gas distribution plate. Alternatively, a gradient spacing may also be created by the plate in combination with a flow gradient by creating a lower concave surface on a downstream surface of the plate. The lower concave surface has a chord depth between about 0.05 inch and about 1 inch. Alternatively, the gradient spacing may be selected with a distance defined between the gas distribution plate and the substrate support assembly of about 50 mils and about 500 mils.

In the embodiment for depositing the intrinsic type microcrystalline silicon layer, a gas mixture of silane gas to hydrogen gas in a ratio between 1:20 and 1:200 may be supplied into the chamber 100 through a gas distribution plate having an upper concave surface. In one embodiment, the concave surface has a chord length between about 0.05 inch and about 1 inch. Silane gas may be provided at a flow rate between about 0.5 sccm/L and about 5 sccm/L. Hydrogen gas may be provided at a flow rate between about 40 sccm/L and about 400 sccm/L. In some embodiments, the silane flow rate may be ramped up from a first flow rate to a second flow rate during deposition. In some embodiments, the hydrogen flow rate may be ramped down from a first flow rate to a second flow rate during deposition. An RF power between about 300 milliWatts/cm² or greater, preferably 600 milliWatts/cm² or greater, may be provided to the gas distribution plate. In some embodiments, the power density may be ramped down from a first power density to a second power density during deposition. The pressure of the chamber is maintained between about 1 Torr and about 100 Torr, preferably between about 3 Torr and about 20 Torr, more preferably between about 4 Torr and about 12 Torr. Alternatively, the pressure during deposition may be segmented into one or more steps, such as ramping up from a first pressure and to a second pressure after processing for a predetermined period. The deposition rate of the intrinsic type microcrystalline silicon layer may be about 200 Å/min or more, preferably 500 Å/min. Methods and apparatus for deposited microcrystalline intrinsic layer that may be adapted for use with a gradient flow producing gas distribution plate are disclosed in U.S. patent application Ser. No. 11/426,127 filed Jun. 23, 2006, entitled “Methods and Apparatus for Depositing a Microcrystalline Silicon Film for Photovoltaic Device,” which is incorporated by reference in its entirety. The microcrystalline silicon intrinsic layer has a crystalline fraction between about 20 percent and about 80 percent, such as between about 55 percent and about 75 percent.

In a particular embodiment for depositing the intrinsic type microcrystalline silicon layer using the gas distribution plate as described herein, the film properties of the deposited microcrystalline silicon layer has improved film property uniformity. For example, as for intrinsic type microcrystalline silicon layer deposited by conventional technique is often found having poor film property uniformity, such as non-uniform crystalline volume at corners of the film. A gas distribution plate configured to provide higher flow resistance at the corners relative to the edges and center results in deposited films having higher crystalline volume as opposed to the film deposited by conventional techniques, thereby providing uniform film properties across the surface of the substrate. In one embodiment, the crystalline volume of the deposited microcrystalline silicon layer using the gas distribution plate having an edge to center flow gradient has demonstrated an improvement crystalline volume non-uniformity from about 70-90 percent in conventional techniques to less than about 3.5 percent. The improved uniformity of the film properties results in increased conversion efficiency, fill factor and improved electrical properties of the solar cells formed on the substrate, thereby improving the overall performance of the cells.

Thus, an apparatus having a gas distribution plate having chokes configured to produce an edge to center gas flow gradient suitable for depositing a silicon film is provided. Silicon films deposited utilizing the inventions are particularly suitable for solar cell applications. The improved apparatus advantageously provide a better control of the film profile and properties deposit on a substrate, thereby increasing the quality control of the film and increasing the photoelectric conversion efficiency and device performance.

While the foregoing is directed to embodiments of the present invention, other and further embodiments of the invention may be devised without departing from the basic scope thereof, and the scope thereof is determined by the claims that follow.

1-20. (canceled)

21. A substrate processing apparatus, comprising:
a processing chamber having a bottom, side walls, and a chamber lid defining a process volume;
a substrate support disposed within the process volume of the processing chamber;
a quadrilateral gas distribution plate having an upstream side and a downstream side disposed within the processing chamber, wherein the quadrilateral gas distribution plate has corner regions with a first plurality of chokes and edge regions with a second plurality of chokes, and wherein the first plurality of chokes has a greater flow resistance than the second plurality of chokes.

22. The apparatus of claim 21, wherein each of the second plurality of chokes has a larger diameter than each of the first plurality of chokes.

23. The apparatus of claim 21, wherein each choke has a first cylindrical shape and a second cylindrical shape having a greater diameter than the first cylindrical shape.

24. The apparatus of claim 23, wherein the first cylindrical shape extends from the upstream side of the quadrilateral gas distribution plate for a first distance and the second cylindrical shape extends from the downstream side of the first cylindrical shape for a second distance.

25. The apparatus of claim 24, wherein the first distance of each of the first plurality of chokes is greater than the first distance of each of the second plurality of chokes.

26. The apparatus of claim 25, wherein the sum of the first and second distances equals the distance between the upstream side and the downstream side of the quadrilateral gas distribution plate.

27. The apparatus of claim 21, wherein each choke has a first cylindrical shape extending downstream from the upstream side of the gas distribution plate for a first distance and a second cylindrical shape extending downstream from the first cylindrical shape for a second distance, and wherein the first cylindrical shape has a different diameter than the second cylindrical shape.

28. The apparatus of claim 27, wherein the first cylindrical shape has a larger diameter than the second cylindrical shape.

29. The apparatus of claim 28, wherein the second distance of the first plurality of chokes is greater than the second distance of the second plurality of chokes.

30. The apparatus of claim 29, wherein each orifice has a conical shape extending from the second cylindrical shape to the downstream side of the quadrilateral gas distribution plate.

31. The apparatus of claim 28, wherein the first cylindrical shape of each of the second plurality of chokes has a larger diameter than the first cylindrical shape of each of the first plurality of orifices.

32. A substrate processing apparatus, comprising:
a processing chamber having a bottom, side walls, and a chamber lid defining a process volume;
a substrate support disposed within the process volume of the processing chamber;
a quadrilateral gas distribution plate having an upstream side and a downstream side disposed within the processing chamber, wherein the quadrilateral gas distribution plate has corner regions with a first plurality of chokes, edge regions with a second plurality of chokes, and a central region with a third plurality of chokes, wherein the first plurality of chokes has a greater flow resistance than the second plurality of chokes, and wherein the second plurality of chokes has a greater flow resistance than the third plurality of chokes.

33. The apparatus of claim 32, wherein each choke has a first cylindrical portion that extends a first distance downstream from the upstream side of the gas distribution plate, and wherein the first distance of each of the first plurality of chokes is greater than the first distance of each of the second plurality of chokes.

34. The apparatus of claim 33, wherein each choke has second portion extending from the downstream side of the first cylindrical portion to the downstream side of the quadrilateral gas distribution plate.

35. The apparatus of claim 34, wherein the diameter of each first cylindrical portion is smaller than a diameter of each second portion extending downstream therefrom.

36. The apparatus of claim 32, wherein each choke has a first cylindrical shape extending from the upstream side of the gas distribution plate a first distance toward the downstream side and a second cylindrical shape extending from the downstream side of the first cylindrical shape a second distance toward the downstream side of the gas distribution plate, wherein the diameter of each of the second cylindrical shape is smaller than a diameter of the first cylindrical shape.

37. The apparatus of claim 36, wherein the second distance of the first plurality of chokes is greater than the second distance of the first plurality of chokes.

38. A method for depositing a film on a substrate in a process chamber, comprising:
placing a substrate onto a substrate support assembly in the process chamber having a gas distribution plate facing the substrate support assembly;
flowing process gas through corner regions of the gas distribution plate toward the substrate at a rate less than a rate of process gas flowing through edge regions of the gas distribution plate; and
depositing a film on the substrate from the process gas.

39. The method of claim 38, wherein the rate of process gas flowing through the edge regions of the gas distribution plate is less than a rate of process gas flowing through a central region of the gas distribution plate.

40. The method of claim 39, wherein flowing the process gas further comprises providing greater flow resistance in the corner regions of the gas distribution plate than in edge regions of the gas distribution plate.
